(19) United States
(12) Patent Application Publication
(10) Pub. No.: US 2010/0254156 A1
(43) Pub. Date: Oct. 7, 2010

(54) MULTI-DIRECTIONAL LIGHT PIPE WITH METERED SIDE SCATTER

(75) Inventor: Mark Alan Yoder, Carmel, IN (US)

Correspondence Address: Robert D. Shedd, Patent Operations;THOMSON Licensing LLC, P.O. Box 5312, Princeton, NJ, 08543-5312, US

(73) Assignee: THOMSON LICENSING a corporation

(21) Appl. No.: 12/734,574

(22) PCT Filed: Mar. 6, 2008
(86) PCT No.: PCT/US2008/002993

§ 371 Date: May 10, 2010

Related U.S. Application Data
(60) Provisional application No. 61/004,835, filed on Nov. 30, 2007.

(51) Int. Cl. H01L 33/02; F21S 4/00; G02B 6/00

(52) U.S. Cl. 362/555; 362/249.01; 362/551

(57) ABSTRACT

The present invention is directed to a light pipe that is used to illuminate a portion of a surface of a set top box when the instrument power is turned on. The light pipe can be molded for example from plastic. The light pipe should advantageously be a good carrier of photons down a linear path. Additionally, light pipe should allow for light to be transmitted out the sides of the part.

### CROSS REFERENCE TO RELATED APPLICATION

This application claims priority to and all benefits accruing from a provisional application filed in the United States Patent and Trademark Office on Nov. 30, 2007, and there assigned Ser. No. 61/004835.

### TECHNICAL FIELD

The invention relates generally to set top boxes for broadband and video connected premises through satellite, cable, telco and Internet service providers.

### BACKGROUND OF THE INVENTION

Some set top boxes include keypads and/or regions that are illuminated when the instrument power is turned on. Such illumination may undesirably interfere with other regions of the instrument.

### BRIEF SUMMARY OF THE INVENTION

The present invention is directed to a light pipe that is used to illuminate a portion of a surface of a set top box when the instrument power is turned on. The light pipe can be molded for example from plastic. The light pipe should advantageously be a good carrier of photons down a linear path. Additionally, light pipe should allow for light to be transmitted out the sides of the part.

### BRIEF SUMMARY OF THE DRAWINGS

FIG. 1 is a side view of a set top box including the light pipe of the present invention;

FIG. 2 is a view of the light pipe showing the direction of light transmission; and

FIG. 3 is a cross-sectional view of an edge of the light pipe showing light transmission around a corner between two sides thereof.

### DETAILED DESCRIPTION

The present invention is directed to a light pipe that is used to illuminate a portion of a surface of a set top box when the instrument power is turned on. The light pipe can be molded for example from a plastic material.

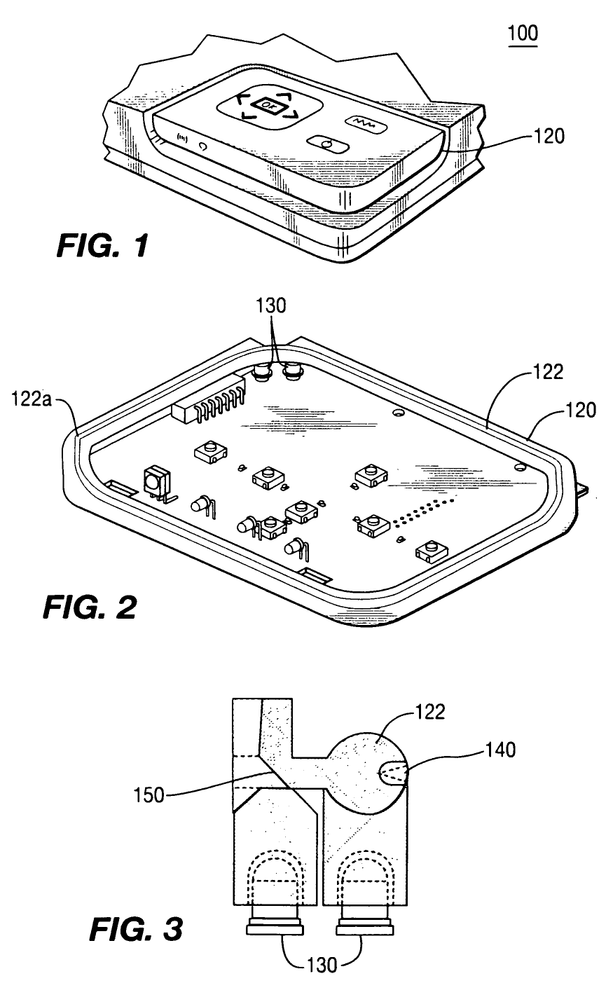

FIG. 1 illustrates a portion of a side view of a set top box 100. The set top box 100. includes a light pipe 122 (FIG. 2). The light pipe 122 illuminates a portion of the surface of the set top box 100. For example, the light pipe may illuminate buttons, command keys or an outline of the surface of the set top box. In one embodiment, the light pipe 122, shown in FIG. 2, illuminates a portion of the surface of the set top box 100 including buttons and command keys.

The light pipe may have various shapes. For example, the light pipe may have an outline that has a square shape, an oval shape, a rectangular shape or a circular shape, among others depending on the characteristics of the set top box 100. Referring to FIG. 2, the light pipe 122 in one exemplary embodiment has a generally rectangular shape.

Light pipes 122 having, for example, a rectangular shape may also include either 90 degree angled edges and/or curved edges. For example referring to FIG. 2, the generally rectangular shaped light pipe 122 has both curved and 90 degree angled edges.

Light can be transmitted at right angles within the light pipe 122 by putting a surface 150 having an angle of about 45 degrees, for example, from the light path (see FIG. 3). Light transmission along the light path is reduced as the angle of incidence for surface 150 approaches the critical angle for total internal reflection (TIR).

In one embodiment, the efficiency of light transmitted along the light path may be improved by increasing the reflectivity of surface 150. For example, the 45 degree angled surfaces may be coated with a reflective material. Examples of suitable reflective materials may include silver paint, silver foil and chrome electro-plating, among others.

The light pipe 122 may be made of a molded plastic material. The plastic material may be pigmented plastic material. Pigmented plastic materials may have any color including for example, red, blue, green, yellow, orange and pink, among others.

Alternatively, the light pipe 122 of the present invention may be formed of a molded plastic material including two or more different segments. For such an embodiment, the two or more different segments may be formed of two or more different pigmented plastic materials. As such, the two or more different segments of such light pipe would be illuminated with different colors.

In one embodiment, the light pipe 122 forms a channel (light path) within a plastic member 120 and is coupled to at least one light source 130. The exemplary light pipe 122 shown in FIG. 2, forms a light path that extends along a portion of the molded plastic member 120. The member 120 may have any shape or width and may encompass all or at least portions of the light pipe 122. The light path may extend along three dimensions. For example, referring to FIG. 2, the light pipe 122 extends along an x-direction and a y-direction from light source 130 within the member 120. Additionally, the light pipe 122 may also extend along a z-direction within the member 120 beginning at point 122a.

The light pipe 122 should advantageously be formed of a material that is a good transmitter of photons along its linear length. Additionally, the material of light pipe 122 should allow for light to be transmitted out the sides thereof.

As shown in FIG. 2 the light pipe 122 is coupled to at least one light source 130. The at least one light source 130 should be sufficient to provide light that will extend along the linear length of the light pipe 122 with generally uniform illumination. Additionally, the at least one light source 130 should be sufficient to transmit light out the sides of the light pipe 122 with generally uniform illumination.

The at least one light source 130 may be positioned anywhere along the length of the light pipe 122. In one exemplary embodiment shown in FIG. 2, two light sources 130 are positioned adjacent to one another at one end of a rectangular shaped light pipe 122. However, when more than one light source 130 is used, such light sources 130 may be positioned at different locations along the light pipe 122. For example, two light sources may be positioned at opposite corners of a rectangular shaped light pipe (not shown).

The at least one light source 130 may be any light source that is suitable for providing light that will extend along the linear length of the light pipe 122 with generally uniform illumination. Additionally, the at least one light source should be sufficient to transmit light out the sides of the light pipe 122 with generally uniform illumination. The at least one light source 130 may be, for example, a light emitting diode.

FIG. 3 is a cross-sectional view of an edge of the light pipe 122 where the one or more light sources 130 provide illumination to the light pipe 122. In one embodiment, the one or more light source 130 provides illumination from the underside of the light pipe 122. FIG. 3 shows light from the light source 130 being provided to the underside of the light pipe 122. In one embodiment, the one or more light sources 130 may provide illumination from a tapered groove 140. The tapered groove 140 should preferably have a taper angle that is less than about 90 degrees. Tapered grooves having angles less than about 90 degrees scatter the light and cause the photons to reflect perpendicularly toward the direction of the light path (see FIG. 3). Such a tapered groove arrangement allows the light to be metered in a controlled fashion to transmit the light around the perimeter of the light pipe 122 in a generally uniform manner.

The foregoing illustrates some of the possibilities for practicing the invention. Many other embodiments are possible within the scope and spirit of the invention. Therefore, it is intended that the foregoing description be regarded as illustrative rather than limiting, and that the scope of the invention is given by the appended claims together with their full range of equivalents.

1. An apparatus, comprising
a housing, wherein one or more portion of the housing is light transmissive; and
at least one light source coupled to the light transmissive portion of the housing.

2. The apparatus of claim 1 wherein the one or more light transmissive portion of the housing is a light pipe.

3. The apparatus of claim 2 wherein the light pipe has angled surfaces.

4. The apparatus of claim 3 wherein the angled surfaces are coated with a material:

5. The apparatus of claim 1 wherein the at least one light source is a light emitting diode (LED).

6. A set top box for broadband and video connected premises, comprising a housing, wherein one or more portion of the housing includes a light pipe; and
at least one light source coupled to the one or more portion of the housing including the light pipe.

7. The set top box of claim 6 wherein the light pipe has angled surfaces.

8. The set top box of claim 7 wherein the angled surfaces are coated with a material.

9. The set top box of claim 6 wherein the at least one light source is a light emitting diode (LED).
